(19) United States
(12) Patent Application Publication
(10) Pub. No.: US 2024/0429151 A1
(43) Pub. Date: Dec. 26, 2024

(54) SEMICONDUCTOR PACKAGE AND METHOD OF MANUFACTURING SEMICONDUCTOR PACKAGE

(71) Applicant: SAMSUNG ELECTRONICS CO., LTD., Suwon-si (KR)

(72) Inventor: Heejin YUN, Suwon-si (KR)

(73) Assignee: SAMSUNG ELECTRONICS CO., LTD., Suwon-si (KR)

(21) Appl. No.: 18/637,746

(22) Filed: Apr. 17, 2024

(30) Foreign Application Priority Data
Jun. 26, 2023 (KR) 10-2023-0082040

(51) Int. Cl. H01L 23/498; H01L 21/48; H01L 23/00; H01L 25/065

(52) U.S. Cl. CPC H01L 23/49838; H01L 21/4846; H01L 23/49822; H01L 24/08; H01L 25/0655; H01L 24/16; H01L 24/32; H01L 24/73; H01L 2224/08225; H01L 2224/16237; H01L 2224/32225; H01L 2224/73204; H01L 2924/19011

(57) ABSTRACT

A semiconductor package includes a package substrate having a first surface and a second surface opposite to each other, the package substrate comprising a plurality of first substrate pads and a plurality of second substrate pads that are exposed from the first surface; a semiconductor device mounted on the first surface of the package substrate; at least one semiconductor element on the package substrate, the at least one semiconductor element spaced apart from the semiconductor device, the at least one semiconductor element being mounted on the package substrate via solder members that are disposed on the plurality of second substrate pads; and a plurality of insulating structures on the first surface of the package substrate to space a lower surface of the at least one semiconductor element from the first surface of the package substrate.

### CROSS-REFERENCE TO RELATED APPLICATION

This application claims priority under 35 U.S.C. § 119 to Korean Patent Application No. 10-2023-0082040, filed on Jun. 26, 2023 in the Korean Intellectual Property Office, the contents of which are herein incorporated by reference in their entirety.

### BACKGROUND

### 1. Field

Example embodiments relate to a semiconductor package and a method of manufacturing the semiconductor package. More particularly, example embodiments relate to a semiconductor package including a semiconductor element and a method of manufacturing the same.

### 2. Description of the Related Art

During a process of mounting semiconductor elements such as capacitors on a package substrate, there are spacing distances between the semiconductor elements and the package substrate. If the spacing distance is not sufficient, voids may occur in a molding member (Epoxy Molding Compound) that covers the semiconductor elements on the package substrate. Furthermore, if the spacing distance is not sufficient, foreign substances may remain in gaps between the semiconductor elements and the package substrate during a following cleaning process, and a failure due to short circuiting may occur due to the foreign substances.

### SUMMARY

Example embodiments provide a semiconductor package having a structure with a sufficient space between semiconductor elements and a package substrate.

Example embodiments provide a method of manufacturing the semiconductor package.

According to one or more embodiments, a semiconductor package, comprising: a package substrate having a first surface and a second surface opposite to each other, the package substrate comprising a plurality of first substrate pads and a plurality of second substrate pads that are exposed from the first surface, wherein the plurality of first substrate pads and the plurality of second substrate pads are electrically connected to each other; a semiconductor device mounted on the first surface of the package substrate and electrically connected to the plurality of first substrate pads; at least one semiconductor element on the package substrate, the at least one semiconductor element spaced apart from the semiconductor device, the at least one semiconductor element being mounted on the package substrate via solder members that are disposed on the plurality of second substrate pads; and a plurality of insulating structures on the first surface of the package substrate to space a lower surface of the at least one semiconductor element from the first surface of the package substrate, each of the plurality of insulating structures having a lower insulator and an upper insulator stacked on the lower insulator.

According to one or more embodiments, A method of manufacturing a semiconductor package comprises providing a package substrate having a plurality of substrate pads that are exposed from a first surface of a package substrate; forming a first insulating layer to cover the first surface of the package substrate; removing at least portions of the first insulating layer to form a plurality of lower insulators on the first surface of the package substrate; forming a second insulating layer on the first surface of the package substrate to cover the lower insulators; removing at least portions of the second insulating layer to form a plurality of upper insulators on the plurality of lower insulators respectively; and mounting a semiconductor element on the plurality of substrate pads via solder members.

According to one or more embodiments, a semiconductor package, comprising: a package substrate having a plurality of first substrate pads and a plurality of second substrate pads that are exposed from a first surface of the package substrate, wherein the plurality of first substrate pads and the plurality of second substrate pads are electrically connected to each other; a semiconductor device mounted on the first surface of the package substrate and electrically connected to the plurality of first substrate pads; a semiconductor element on the first surface of the package substrate, the semiconductor element spaced apart from the semiconductor device, the semiconductor element being mounted on the package substrate via solder members that are disposed on the plurality of second substrate pads; and a plurality of insulating structures provided within the solder members on the plurality of second substrate pads respectively, each of the plurality of insulating structures comprising a lower insulator provided on a central region of the second substrate pads and an upper insulator provided on the lower insulator, wherein a lower surface of the semiconductor element is spaced from the first surface of the package substrate by the plurality of insulating structures.

Accordingly, the plurality of insulating structures may support the semiconductor element on the second substrate pads. The plurality of insulating structures may increase and maximize a space between the semiconductor element and the package substrate. The plurality of insulating structures may prevent voids from occurring and foreign substances from remaining between the semiconductor element and the package substrate through the space.

The plurality of insulating structures may be provided on the second substrate pads and may have a stepping stone structure in which the insulating structures are spaced apart from each other. Through the stepping stone structure, the plurality of insulating structures may increase or maximize bonding areas between the solder members and the second substrate pads.

Further, during a process of forming an uppermost insulating layer on the package substrate, the plurality of insulating structures may be formed together with the uppermost insulating layer. Since the plurality of insulating structures may be formed without additional process equipment, manufacturing times and manufacturing costs may be reduced.

### BRIEF DESCRIPTION OF DRAWINGS

Example embodiments will be more clearly understood from the following detailed description taken in conjunction with the accompanying drawings. FIGS. 1 to 14 represent non-limiting, example embodiments as described herein.

FIG. 1 is a plan view illustrating a semiconductor package in accordance with example embodiments.

FIG. 2 is a cross-sectional view taken along the line A-A′ in FIG. 1, according to one or more embodiments.

FIG. 3 is a perspective view illustrating a semiconductor element disposed on a semiconductor substrate, according to one or more embodiments.

FIG. 4 is a cross-sectional view taken along the line B-B′ in FIG. 3, according to one or more embodiments.

FIG. 5 is a cross-sectional view taken along the line C-C′ in FIG. 3, according to one or more embodiments.

FIG. 6 is a plan view illustrating the semiconductor element disposed on the semiconductor substrate, according to one or more embodiments.

FIGS. 7 to 14 are views illustrating a method of manufacturing a semiconductor package in accordance with example embodiments.

### DETAILED DESCRIPTION OF EXAMPLE EMBODIMENTS

Hereinafter, example embodiments will be explained in detail with reference to the accompanying drawings.

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

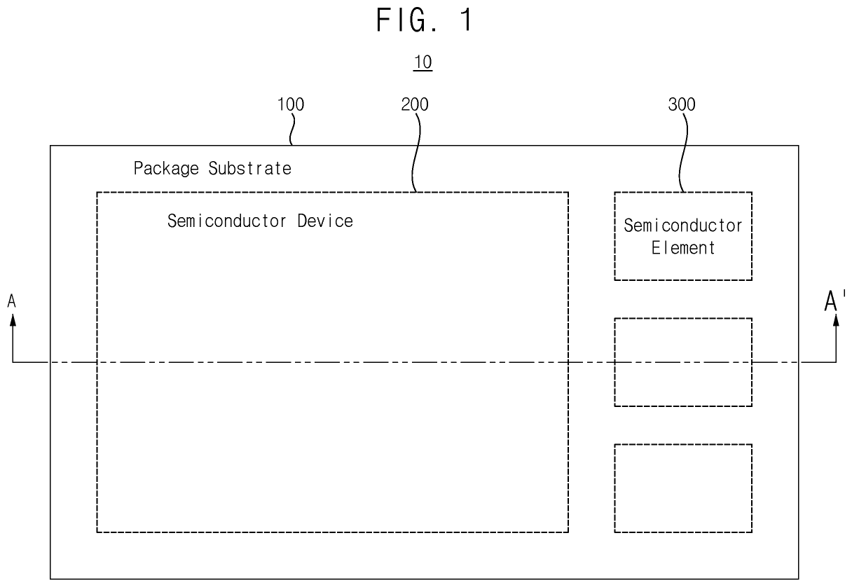

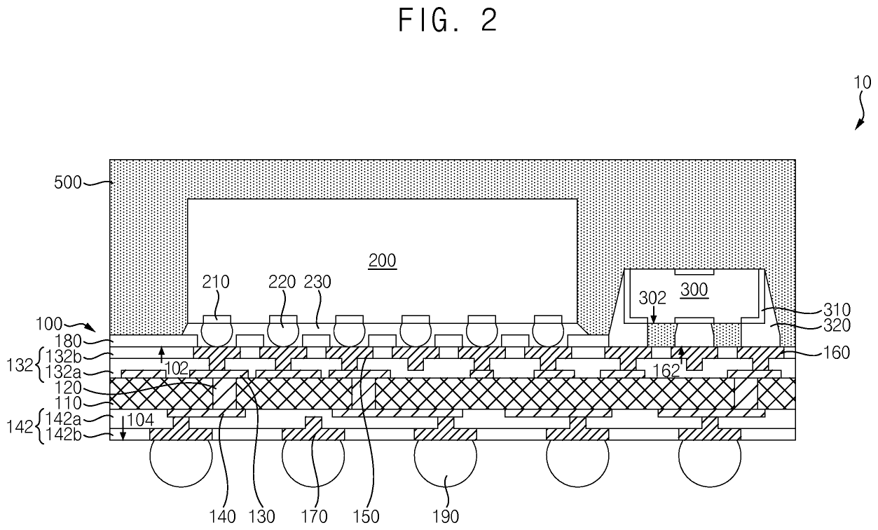

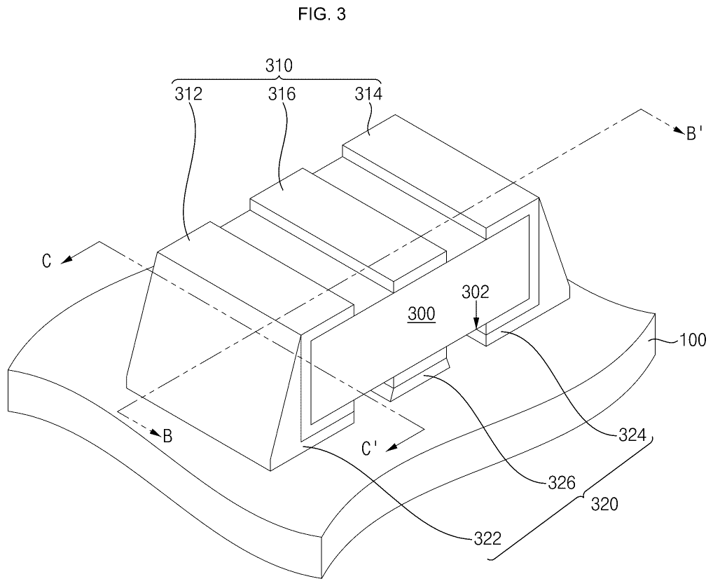

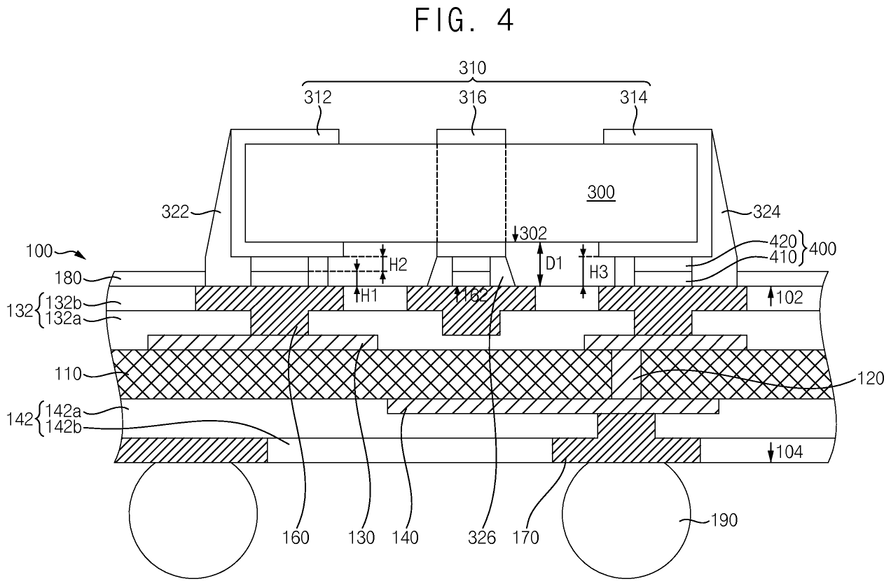

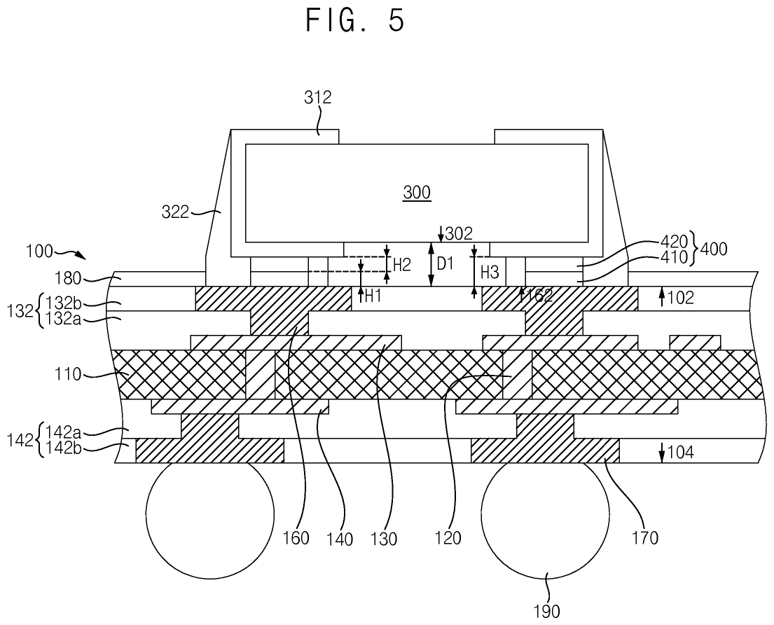

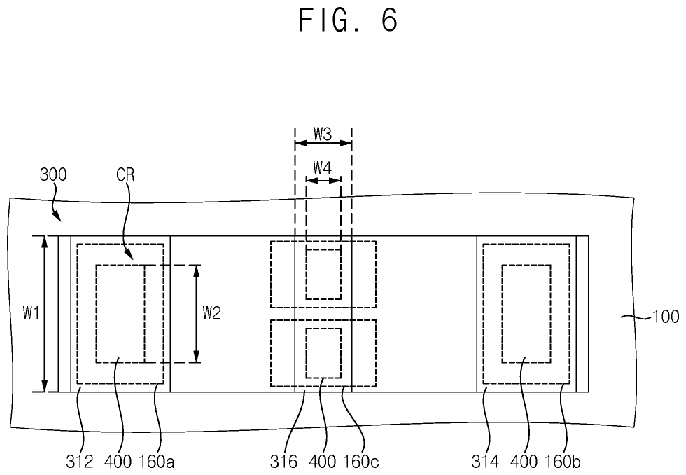

FIG. 1 is a plan view illustrating a semiconductor package in accordance with example embodiments. FIG. 2 is a cross-sectional view taken along the line A-A′ in FIG. 1. FIG. 3 is a perspective view illustrating a semiconductor element disposed on a semiconductor substrate. FIG. 4 is a cross-sectional view taken along the line B-B′ in FIG. 3. FIG. 5 is a cross-sectional view taken along the line C-C′ in FIG. 3. FIG. 6 is a plan view illustrating the semiconductor element disposed on the semiconductor substrate.

Referring to FIGS. 1 to 6, a semiconductor package 10 may include a package substrate 100, at least one semiconductor device 200 disposed on the package substrate 100, and at least one semiconductor element 300 electrically connected to the semiconductor device 200, and a plurality of insulating structures 400 provided between the semiconductor element 300 and the package substrate 100. The semiconductor package 10 may further include a sealing member 500. As illustrated in FIG. 2, the sealing member 500 covers the at least one semiconductor device 200 and the at least one semiconductor element 300.

In example embodiments, the semiconductor device 200 and the semiconductor element 300 may be connected to each other through wirings in the package substrate 100. The semiconductor device 200 may include conductive bumps 220 that are provided respectively on chip pads 210 on a lower surface thereof. The semiconductor element 300 may include solder members 320 that are provided on element pads 310 thereof. As understood by one of ordinary skill in the art, any desired number of solder members 320 may be used to fix a device or element on a surface. The semiconductor device 200 and the semiconductor element 300 may be mounted on the package substrate 100, and may be electrically connected via the conductive bumps 220 and the solder members 320.

In example embodiments, the package substrate 100 may be a substrate having a first surface 102 and a second surface 104 opposite to each other. For example, the package substrate 100 may include a printed circuit board (PCB), a flexible substrate, a tape substrate, etc. The printed circuit board may be a multilayer circuit board having vias and various circuits therein.

The package substrate 100 may include a core layer 110, a plurality of conductive through vias 120, upper conductive patterns 130, an upper insulating layer 132, lower conductive patterns 140, a lower insulating layer 142, a plurality of first to third substrate pads 150, 160 and 170, respectively, and an uppermost insulating layer 180. The package substrate 100 may further include a plurality of external connection bumps 190.

The core layer 110 may include a non-conductive material layer. The core layer 110 may include a reinforcing polymer or any other suitable material known to one of ordinary skill in the art. The conductive through via 120 may penetrate the core layer 110 and may electrically connect the upper conductive pattern 130 and the lower conductive pattern 140.

The first and second substrate pads 150 and 160, respectively, may be provided on the core layer 110 such that upper surfaces of the first and second substrate pads 150 and 160, respectively, form portions of the first surface 102 of the package substrate 100. The first and second substrate pads 150 and 160 may be electrically connected to the upper conductive patterns 130. As illustrated in FIG. 2, the first and second substrate pads 150 and 160 may be provided in an alternating fashion. The upper conductive patterns 130 may extend inside the package substrate 100. The upper conductive patterns 130 may be provided in the upper insulating layer 132. The upper conductive patterns 130 may extend on an upper surface of the core layer 110. For example, at least portions of the upper conductive patterns 130 may be used as landing pads for the first and second substrate pads 150 and 160, respectively.

The third substrate pads 170 may be disposed on a side of the core layer 110 that is opposite to a side on which the first substrate pads 150 and second substrate pads 160 are disposed. Lower surfaces of the third substrate pads 170 may form portions of the second surface 104 of the package substrate 100, where the third substrate pads 170 may be electrically connected to the lower conductive patterns 140. The lower conductive patterns 140 may extend within the package substrate 100. The lower conductive patterns 140 may be provided in the lower insulating layer 142. The lower conductive patterns 140 may extend on a lower surface of the core layer 110 opposite to the upper surface. For example, at least portions of the lower conductive patterns 140 may be used as landing pad for the third substrate pads 170.

The upper conductive patterns 130 and the lower conductive patterns 140 may include a power wire or a ground wire as a power net for supplying power to electronic components mounted on the package substrate 100. The first to third substrate pads 150, 160 and 170, respectively, may include a power pad or a ground pad connected to the power wire or ground wire. In one or more examples, the first to third substrate pads 150, 160 and 170 may further include a plurality of substrate signal wirings and substrate signal pads for transmitting data signals to the electronic components.

For example, the upper and lower conductive patterns 130 and 140, respectively, and the first to third substrate pads 150, 160, and 170, respectively, may include aluminum (Al), copper (Cu), tin (Sn), and nickel (Ni), gold (Au), platinum (Pt), or an alloy thereof. The upper and lower conductive patterns 130 and 140, respectively, and the first to third substrate pads 150, 160, and 170, respectively, may be formed by a plating process, an electroless plating process, a vapor deposition process, etc.

The upper insulating layer 132 may be provided within the package substrate 100. The upper insulating layer 132 may cover the upper conductive patterns 130 while contacting side surfaces of the first and second substrate pads 150 and 160, respectively, and not covering upper surfaces of the first and second substrate pads 150 and 160, respectively, such that the first and second substrate pads 150 and 160, respectively are exposed from the first surface 102 of the package substrate 100. For example, the upper insulating layer 132 may correspond to the entire first surface 102 of the package substrate 100 except the upper surfaces of the first and second substrate pads 150 and 160, respectively. As illustrated in FIG. 2, the first surface 102 may be formed by a combination of the upper insulating layer 132 and the upper surfaces of the first and second substrate pads 150 and 160, respectively.

The uppermost insulating layer 180 may be provided on the first surface 102 of the package substrate 100. The uppermost insulating layer 180 may be provided on the upper insulating layer 132. The uppermost insulating layer 180 may cover at least portions of the first and second substrate pads 150 and 160, respectively, such that portions of the first and second substrate pads 150 and 160, respectively, that are not covered by the uppermost insulating layer 180 are exposed.

The uppermost insulating layer 180 may have an opening area for mounting the semiconductor element 300 on the first surface 102 of the package substrate 100. The uppermost insulating layer 180 may expose the second substrate pads 160 through the opening area.

The uppermost insulating layer 180 may be formed of an insulating material and may protect the package substrate 100 from the outside. The uppermost insulating layer 180 may be formed of an oxide layer or a nitride layer, or may be formed of a double layer of an oxide layer and a nitride layer. The uppermost insulating layer 180 may be formed of an oxide layer, for example, a silicon oxide layer (SiO₂) using a high-density plasma chemical vapor deposition (HDP-CVD) process.

The lower insulating layer 142 may be provided on a side of the core layer 110 opposite to the upper insulating layer 132. The upper insulating layer 142 may cover the lower conductive patterns 140 while contacting side surfaces of the third substrate pads 170 and not covering lower surfaces of the third substrate pads 170 such that the third substrate pads 170 are exposed. As illustrated in FIG. 2, the second surface 104 may be composed of the lower insulating layer 142 and lower surfaces of the third substrate pads 170. In one or more examples, the upper and lower insulating layers 132 and 142 may include a polymer, a dielectric film, a silicon oxide layer, a silicon nitride layer, or a silicon oxynitride layer. The upper and lower insulating layers 132 and 142 may be formed by a vapor deposition process, a spin coating process, etc.

The third substrate pads 170 may be provided on a side of the core layer 110 opposite to the side on which the first and second substrate pads 150 and 160, respectively are provided, where lower surfaces of the third substrate pads 170 form portions of the second surface 104 of the package substrate 100. The external connection bumps 190 may be provided respectively on the third substrate pads 170 for electrical connection with an external device. The external connection bumps 190 may be exposed by the lower insulating layer 142. For example, the external connection bump 190 may be a solder ball. The semiconductor package 10 may be mounted on a module substrate via the solder balls to form a semiconductor module.

Although only some substrate pads and the wirings are illustrated in the drawings, it may be understood by one of ordinary skill in the art that the number and arrangement of the substrate pad and the wirings are exemplary, and it may be not limited thereto. Since the wirings as well as the substrate pads are well known in the art to which the present embodiments pertain, illustration and description concerning the above elements will be omitted.

In example embodiments, the semiconductor device 200 may be disposed directly or indirectly on the first surface 102 of the package substrate 100. The semiconductor device 200 may be mounted on the package substrate 100 using a flip chip bonding method. The semiconductor device 200 may be electrically connected to the first substrate pads 150. The chip pads 210 of the semiconductor device 200 may be electrically connected to the first substrate pads 150 of the package substrate 100 through the conductive bumps 220 that serve as conductive connection members. For example, the conductive bumps 220 may include micro bumps (uBumps).

In one or more examples, the semiconductor device 200 may be mounted on the package substrate 100 using a wire bonding method. The chip pads 210 of the semiconductor device 200 may be electrically connected to the first substrate pads 150 of the package substrate 100 through bonding wires that serve as conductive connection members.

A first adhesive 230 may be underfilled between the semiconductor device 200 and the package substrate 100. For example, the first adhesive 230 may serve as an underfill layer between the semiconductor device 200 and the package substrate 100. The first adhesive 230 may reinforce a gap between the semiconductor device 200 and the package substrate 100.

In example embodiments, the semiconductor element 300 may be disposed on the first surface 102 of the package substrate 100. The semiconductor element 300 may be spaced apart from the semiconductor device 200 on the package substrate 100. The semiconductor element 300 may be electrically connected to the semiconductor device 200 to eliminate electrical noise and ensure that power is supplied uniformly. A plurality of the semiconductor elements 300 may be disposed on the package substrate 100. For example, the number of semiconductor elements 300 may range from 2 to 15, or any other suitable number of semiconductor elements based on the size of the package substrate 100.

In one or more examples, the semiconductor element 300 may include a passive element, a multi-layer ceramic capacitor (MLCC), a low inductance chip capacitor (LICC), a die side capacitor (DSC), a land side capacitor (LSC), an inductor, an integrated passive device (IPD), etc.

The semiconductor element 300 may include the element pads 310 and the solder members 320. The semiconductor element 300 may be mounted on the package substrate 100 using a flip chip bonding method. The semiconductor element 300 may be electrically connected to the second substrate pads 160. The element pads 310 of the semiconductor element 300 may be electrically connected to the second substrate pads 160 of the package substrate 100 through the solder members 320 that serve as conductive connection members. For example, the solder members 320 may include micro bumps (uBumps).

The element pads 310 may include first and second pads 312 and 314, respectively, provided in both sides of the semiconductor element 300, and a central pad 316 provided between the first and second pads 312 and 314, respectively. The element pads 310 may be exposed from a lower surface 302 of the semiconductor element 300. The element pads 310 may be electrically connected to the solder members 320.

The solder members 320 may include first and second conductive members 322 and 324, respectively, that contact and are electrically connected to the first and second pads 312 and 314, respectively, and a central conductive member 326 that contacts and is electrically connected to the central pad 316. The solder members 320 may electrically connect the element pads 310 to the second substrate pads 160.

The solder members 320 may be provided to accommodate the insulating structures 400. The solder members 320 may surround the insulating structures 400 and may accommodate the insulating structures 400 in cavities of the solder members 320. The solder members 320 may be supported through the insulating structures 400. The solder members 320 may support the semiconductor element 300 on the lower surface 302 of the semiconductor element 300. The solder members 320 may support vertical stress applied to an upper surface of the semiconductor element 300 opposite to the lower surface 302.

The lower surface 302 of the semiconductor element 300 may be spaced apart from the first surface 102 of the package substrate 100 by a first distance D1. The lower surface 302 of the semiconductor element 300 may be spaced apart from the upper surfaces 162 of the second substrate pads 160 by the first distance D1. The first distance D1 may be increased by the insulating structures 400 that are provided within the solder members 320. For example, the first distance D1 may be within a range of 20 μm to 40 μm (e.g., 20 μm≤D1≤40 μm).

In example embodiments, the insulating structures 400 may be provided on the first surface 102 of the package substrate 100. The insulating structures 400 may be provided without limitation (e.g., any desired configuration) on the package substrate 100 below the semiconductor element 300. The insulating structures 400 may be provided in the opening area of the uppermost insulating layer 180. The insulating structures 400 may be provided on the second substrate pads 160, respectively. The insulating structures 400 may be covered by the solder members 320, respectively. A distance between the lower surface 302 of the semiconductor element 300 from the first surface 102 of the package substrate 100 may be increased by the insulating structures 400.

As illustrated in FIG. 6, the insulating structures 400 may be provided on the first pad 312, the second pad 314, and the central pad 316, respectively. The insulating structures 400 may be provided to be surrounded by the first conductive member 322, the second conductive member 324 (FIG. 5), and the central conductive member 326 (FIG. 5), respectively. The insulating structures 400 may be formed on the second substrate pad 160a provided on the first pad 312, the second substrate pad 160b provided on the second pad 314, and the second substrate pad 160c provided on the central pad 316.

The insulating structures 400 may include lower insulators 410 provided on the second substrate pads 160 and upper insulators 420 respectively stacked on the lower insulators 410. Accordingly, the insulating structures 400 may have a double-layer structure, and may increase the first distance D1 between the semiconductor element 300 and the package substrate 100.

Each of the insulating structures 400 may be provided in a central region CR of each of the second substrate pads 160. The insulating structures 400 may be provided in the central regions CR of the second substrate pads 160 within the solder members 320 to stably support the semiconductor element 300. Because the insulating structures 400 may be provided in the central regions CR of the second substrate pads 160, the insulating structures 400 may be completely covered by the solder members 320. Accordingly, the solder members 320 and the second substrate pads 160 may be stably electrically connected to each other.

The lower insulator 410 and the uppermost insulating layer 180 may be formed by the same process. The lower insulator 410 and the uppermost insulating layer 180 may include the same insulating material. For example, the same insulating material may include a polymer, a dielectric layer, a silicon oxide layer, a silicon nitride layer, or a silicon oxynitride layer.

Each of the element pads 310 may have a first width W1 in a first direction. Each of the insulating structures 400 may have a second width W2 in the first direction. For example, a ratio W2/W1 of the first width W1 and a second width W2 may be within a range of 1/5 to 1/2.

Each of the element pads 310 may have a third width W3 in a second direction perpendicular to the first direction. Each of the insulating structures 400 may have a fourth width W4 in the second direction. For example, a ratio W4/W3 of the third width W3 and the fourth width W4 may be within the range of 1/5 to 1/2.

Because the insulating structures 400 are formed to have the ratio W2/W1 of the first width W1 and the second width W2 and the ratio W4/W3 of the third width W3 and the fourth width W4, the insulating structures 400 may stably support the semiconductor element 300, and the insulating structures 400 may not interfere with the electrical connection between the solder members 320 and the element pads 310.

The lower insulators 410 may have a first height H1 (FIG. 5) from the upper surface 162 of the second substrate pad 160. The upper insulators 420 may have a second height H2 (FIG. 5) from the upper surface of the lower insulators 410. For example, the first height H1 may be within a range of 10 μm to 20 μm (e.g., 10 μm≤H1≤20 μm). The second height H2 may be within a range of 10 μm to 20 μm (e.g., 10 μm≤H2≤20 μm).

Accordingly, the insulating structures 400 may have a third height H3 from the upper surfaces 162 of the second substrate pads 160. The insulating structures 400 may sufficiently space the upper surface 162 of the second substrate pad 160 from the lower surface 302 of the semiconductor element 300 through the third height H3. For example, the third height H3 may be combination of heights H1 and H2, and may be within a range of 20 μm to 40 μm (e.g., 20 μm≤H3≤40 μm).

The insulating structures 400 may be provided on the second substrate pads 160 respectively and may have a stepping stone structure in which the insulating structures 400 are spaced apart from each other. The insulating structures 400 may increase or maximize bonding areas between the solder members 320 and the second substrate pads 160 through the stepping stone structure. The insulating structures 400 may not interfere with the electrical connection between the semiconductor element 300 and the package substrate 100 through the stepping stone structure, and may increase the spacing distance between the semiconductor element 300 and the package substrate 100.

For example, the insulating structures 400 may include die attach film (DAF), epoxy molding compound (EMC), epoxy resin, UV resin, polyurethane, polyurethane resin, silicone resin, silica filler, etc.

The sealing member 500 may be provided to cover the semiconductor device 200 and the semiconductor element 300 on the package substrate 100. The sealing member 500 may fill the space between the package substrate 100 and the semiconductor element 300. For example, the sealing member may include an epoxy mold compound (EMC).

As mentioned above, the plurality of insulating structures 400 may support the semiconductor element 300 on the second substrate pads 160. The plurality of insulating structures 400 may increase and maximize the space between the semiconductor element 300 and the package substrate 100. The plurality of insulating structures 400 may advantageously prevent voids from occurring and foreign substances from remaining between the semiconductor element 300 and the package substrate 100 through the space.

The plurality of insulating structures 400 may be provided on the second substrate pads 160 and have a stepping stone structure in which the insulating structures 400 are spaced apart from each other. Due to the stepping stone structure, the plurality of insulating structures 400 may increase or maximize bonding areas between the solder members 320 and the second substrate pads 160.

Hereinafter, a method of manufacturing the semiconductor package of FIG. 1 will be described.

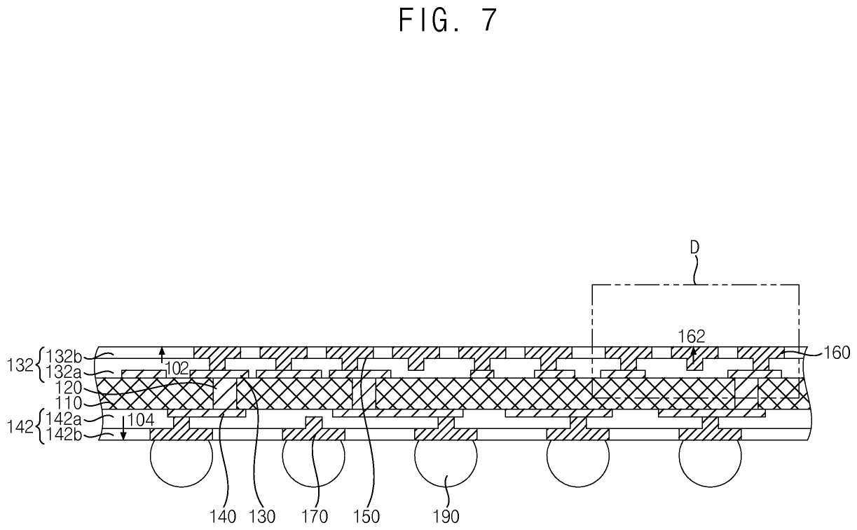

FIGS. 7 to 14 are views illustrating a method of manufacturing a semiconductor package in accordance with example embodiments.

Referring to FIG. 7, a package substrate 100 having a first surface 102 and a second surface 104 opposite to each other may be provided.

In example embodiments, the package substrate 100 including a core layer 110, a plurality of conductive through vias 120 penetrating the core layer 110, a plurality of upper and lower conductive patterns 130 and 140, upper and lower insulating layers 132 and 142, and a plurality of first to third substrate pads 150, 160 and 170 may be formed.

The core layer 110 may include a non-conductive material layer. The core layer 110 may include a reinforcing polymer or the like. The core layer 110 may serve as a boundary layer that divides upper and lower portions of the package substrate 100. The upper insulating layer 132 including first and second upper insulating layer 132a and 132b, respectively, may be formed on the core layer 110. The lower insulating layer 142 including first and second lower insulating layers 142a and 142b, respectively, may be formed on the core layer 110 on a side opposite to a side on which the upper insulating layer 132 is formed.

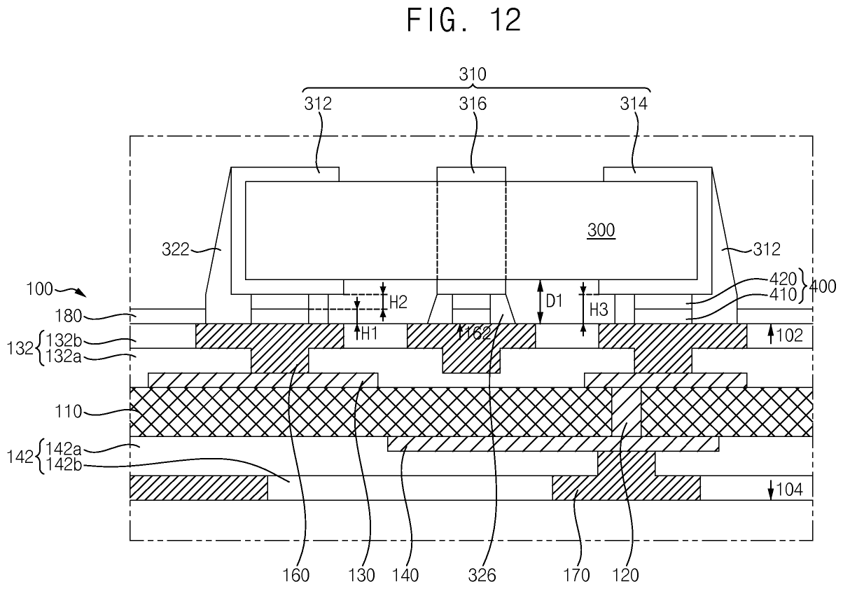

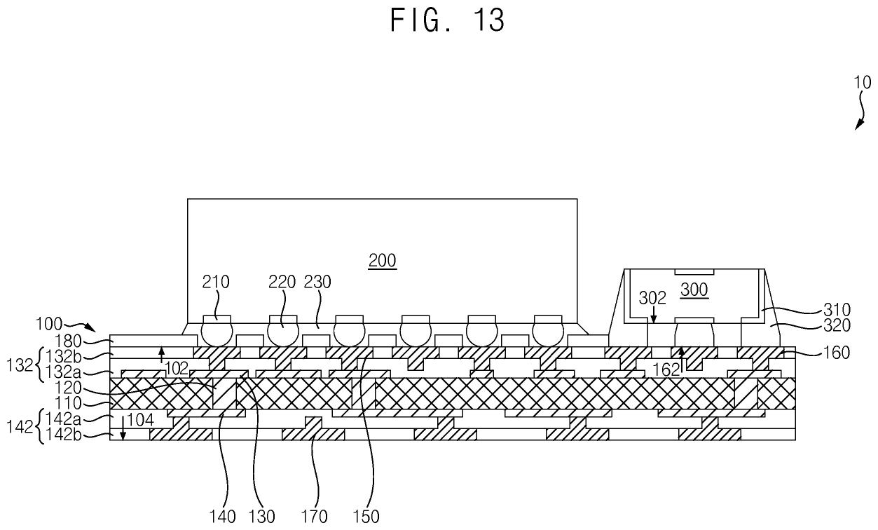

The conductive through via 120 may penetrate the core layer 110 and may electrically connect the upper conductive pattern 130 and the lower conductive pattern 140. When a semiconductor device 200 (see FIG. 13) and a semiconductor element 300 (see FIG. 12) are mounted on the first surface 102 of the package substrate 100, the conductive through via 120 may electrically connect the semiconductor device 200, the semiconductor element 300 and other semiconductor devices provided on the second surface 104 of the package substrate 100.

The first upper insulating layer 132a may be formed to cover an upper surface of the core layer 110, and the first lower insulating layer 142a may be formed to cover a lower surface of the core layer 110. The first upper insulating layer 132a may be patterned to form upper opening patterns that expose portions of the upper surface of the core layer 110, and the first lower insulating layer 142a may be patterned to form lower opening patterns that expose portions of the lower surface of the core layer 110.

The upper conductive patterns 130 may be formed on the first upper insulating layer 132a to directly contact the core layer 110 through the upper opening patterns. A first plating process may be performed on the first upper insulating layer 132a to form the upper conductive patterns 130. The lower conductive patterns 140 may be formed on the first lower insulating layer 142a to directly contact the core layer 110 through the lower opening patterns. A second plating process may be performed on the first lower insulating layer 142a to form the lower conductive patterns 140.

For example, the first and second plating processes may include an electrolytic plating process or an electroless plating process. The upper and lower conductive patterns 130 and 140 may include aluminum (Al), copper (Cu), tin (Sn), nickel (Ni), gold (Au), platinum (Pt), or an alloy thereof.

After the first upper insulating layer 132a is formed, the second upper insulating layer 132b may be formed on the first upper insulating layer 132a to cover the upper conductive patterns 130, and then, the second upper insulating layer 132b may be patterned to form first and second openings that expose the upper conductive patterns 130. The first substrate pads 150 may be formed on the second upper insulating layer 132b to directly contact the upper conductive patterns 130 through the first openings. The second substrate pads 160 may be formed on the second upper insulating layer 132b to directly contact the upper conductive patterns 130 through the second openings.

After the second lower insulating layer 142b is formed on the first lower insulating layer 142a to cover the lower conductive patterns 140, and, the second lower insulating layer 142b may be patterned to form third openings that expose the lower conductive patterns 140. The third substrate pads 170 may be formed on the second lower insulating layer 142b to directly contact the lower conductive patterns 140 through the third openings.

For example, the first to third substrate pads 150, 160 and 170 may include aluminum (Al), copper (Cu), tin (Sn), nickel (Ni), gold (Au), platinum (Pt) or an alloy thereof. For example, the upper and lower insulating layers 132 and 142 may include polymer, dielectric layer, etc. In particular, the upper and lower insulating layers 132 and 142 may include polyimide (PI), lead oxide (PbO), polyhydroxystyrene (PHS), novolac (NOVOLAC), etc. The upper and lower insulating layers 132 and 142 may be formed by a vapor deposition process, spin coating process, etc.

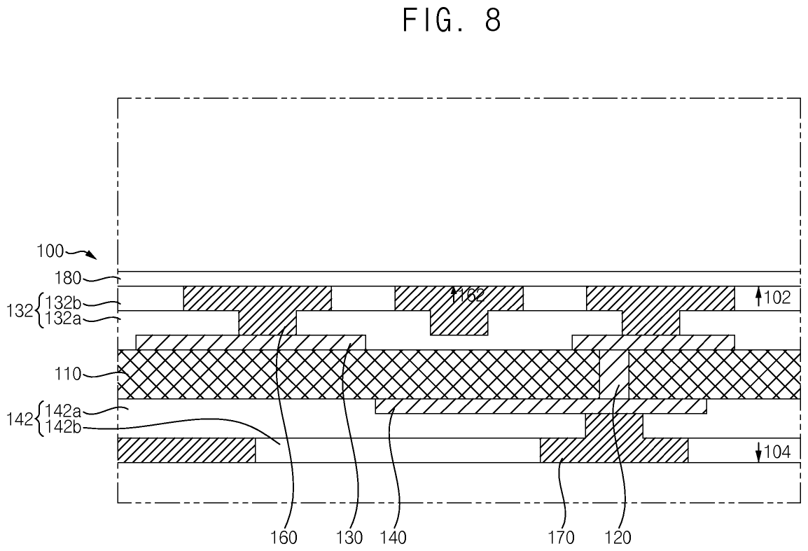

FIGS. 8 to 12 are enlarged cross-sectional views illustrating portion ‘D’ in FIG. 7.

Referring to FIGS. 8 to 11, an uppermost insulating layer 180 and insulating structures 400 may be formed on the upper insulating layer 132 of the package substrate 100.

In example embodiments, the insulating structures 400 may be formed on the second substrate pads 160 of the package substrate 100, respectively. The insulating structures 400 may include a lower insulator 410 and an upper insulator 420 stacked on the lower insulator 410.

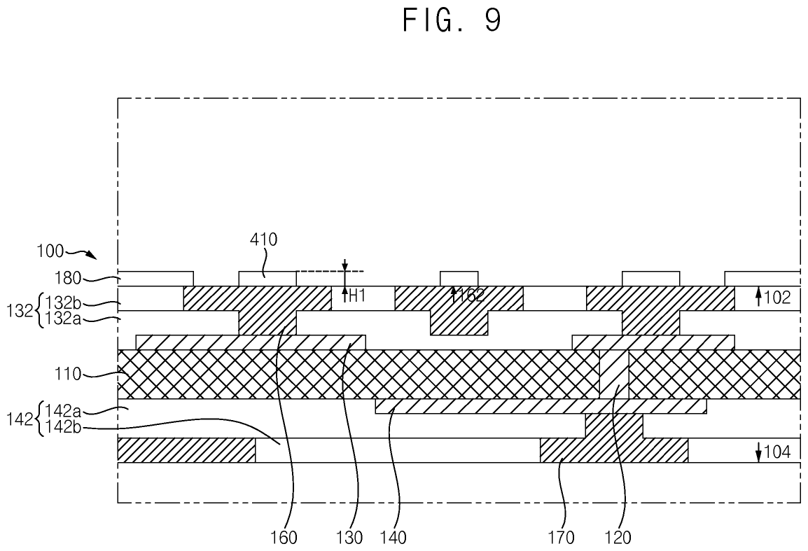

As illustrated in FIGS. 8 and 9, first, the uppermost insulating layer (first insulating layer) 180 may be formed on the first surface 102 of the package substrate 100, and a first etching process may be performed on the first insulating layer 180 to form the lower insulators 410. The lower insulators 410 may be formed on the second substrate pads 160 by the first etching process. The lower insulator 410 and the uppermost insulating layer 180 may include the same insulating material.

The lower insulator 410 may have a first height H1 (FIG. 4) from an upper surface 162 of the second substrate pad 160. For example, the first height H1 may be within a range of 10 μm to 20 μm (e.g., 10 μm≤H1≤20 μm).

For example, the uppermost insulating layer 180 may be formed by a vapor deposition process, a spin coating process, etc. The same insulating material may include a polymer, a dielectric layer, a silicon oxide layer, a silicon nitride layer, or a silicon oxynitride layer.

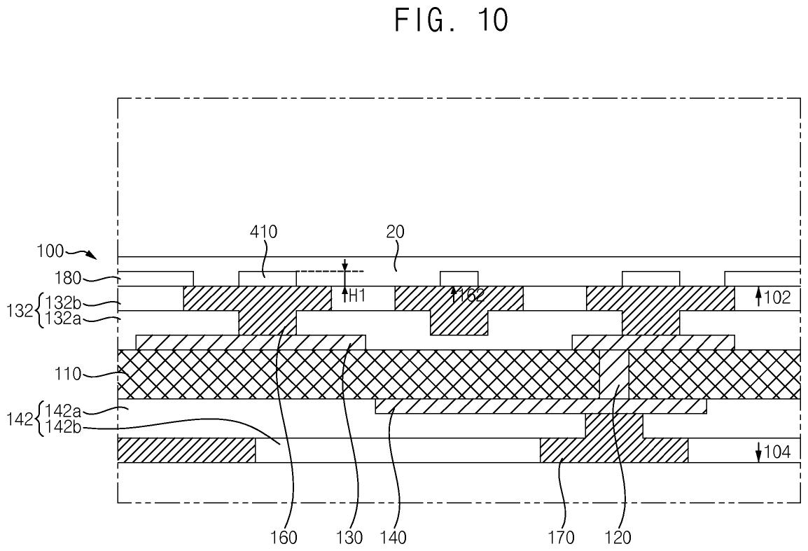

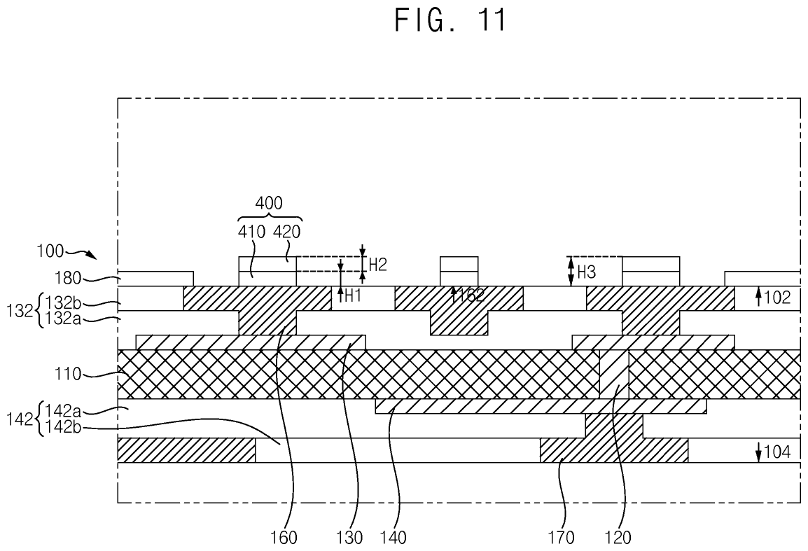

As illustrated in FIGS. 10 and 11, a temporary insulating layer (second insulating layer) 20 may be formed on the uppermost insulating layer 180, and a second etching process may be performed on the temporary insulating layer 20 to form the upper insulators 420. The upper insulators 420 may be formed on the lower insulators 410 by the second etching process, respectively.

The upper insulator 420 may have a second height H2 (FIG. 12) from an upper surface of the lower insulator 410. For example, the second height H2 may be within a range of 10 μm to 20 μm (e.g., 10 μm≤H1≤20 μm).

For example, the temporary insulating layer 20 may be formed by a vapor deposition process, a spin coating process, etc. The upper insulator 420 may include a polymer, a dielectric layer, a silicon oxide layer, a silicon nitride layer, or a silicon oxynitride layer.

The first and second etching processes may include a wet etching process, a dry etching process, a plasma etching process, etc.

The wet etching process may be performed using an etchant having an etch selectivity with respect to the uppermost insulating layer 180 or the temporary insulating layer 20. For example, the etchant may include water (H₂O), hydrogen peroxide (H₂O₂), citric acid (C₆H₈O₇), etc.

For example, the dry etching process may include a physical etching process, a chemical etching process, a physical chemical etching process, etc. The plasma etching process may be performed using inductively coupled plasma, capacitively coupled plasma, microwave plasma, etc.

Referring to FIG. 12, the semiconductor element 300 may be mounted on the package substrate 100.

In example embodiments, the semiconductor element 300 may be disposed on the first surface 102 of the package substrate 100. The semiconductor element 300 may be mounted on the package substrate 100 using a flip chip bonding method. A plurality of the semiconductor elements 300 may be disposed on the package substrate 100. For example, the number of semiconductor elements 300 may be within a range from 2 to 15.

The semiconductor element 300 may be attached to the first surface 102 of the package substrate 100 by performing a thermal compression process at a predetermined temperature (for example, about 400° C. or less). The thermal compression process may include a reflow process. The reflow process may be a process that applies a high-temperature heat source to stably bond the semiconductor element 300 to the package substrate 100.

In the thermal compression process, an external force may be applied to an upper surface of the semiconductor element 300 and the second surface 104 of the package substrate 100. The semiconductor element 300 and the package substrate 100 may be bonded to each other by the external force and the high temperature heat source. For example, solder members 320 of the semiconductor element 300 may be bonded to the second substrate pads 160 that are formed on the first surface 102 of the package substrate 100, respectively.

In the thermal compression process, the solder members 320 may be melted. The molten solder members 320 may cover the insulating structures 400. The molten solder members 320 may not be shorted to each other by the insulating structures 400, and may space a lower surface 302 of the semiconductor element 300 from the upper surfaces 162 of the second substrate pads 160. The solder members 320 covering the insulating structures 400 may be solidified and stably support the semiconductor device 200 on the package substrate 100.

The semiconductor element 300 may be electrically connected to the second substrate pads 160. Element pads 310 of the semiconductor element 300 may be electrically connected to the second substrate pads 160 of the package substrate 100 by the solder members 320 that serve as conductive connection members. For example, the solder members 320 may include micro bumps (uBumps).

The element pads 310 may include first and second pads 312 and 314 provided on both sides of the semiconductor element 300, and a central pad 316 provided between the first and second pads 312 and 314. The solder members 320 may include first and second conductive members 322 and 324 that contact and are electrically connected to the first and second pads 312 and 314, respectively, and a central conductive member 326 that contacts and is electrically connected to the central pad 316. The solder members 320 may electrically connect the element pads 310 and the second substrate pads 160 respectively.

The lower surface 302 of the semiconductor element 300 may be spaced apart from the first surface 102 of the package substrate 100 by a first distance D1. The lower surface 302 of the semiconductor element 300 may be spaced apart from the upper surfaces 162 of the second substrate pads 160 by the first distance D1. For example, the first distance D1 may be within a range of 20 μm to 40 μm (e.g., 20 μm≤D1≤40 μm).

Referring to FIG. 13, the semiconductor device 200 may be mounted on the package substrate 100 using the flip chip bonding method. The semiconductor device 200 may be attached to the package substrate 100 by a thermal compression process.

The semiconductor device 200 may be bonded to the first substrate pads 150 by conductive bumps 220 that are provided on chip pads 210 thereof. The semiconductor device 200 and the semiconductor element 300 may be electrically connected to each other through the first and second substrate pads 150 and 160 of the package substrate 100 and the upper conductive pattern 130.

Then, a first adhesive 230 may be underfilled between the semiconductor device 200 and the package substrate 100. For example, the first adhesive 230 may form an underfilled layer between the semiconductor device 200 and the package substrate 100. The first adhesive 230 may advantageously reinforce a gap between the semiconductor device 200 and the package substrate 100.

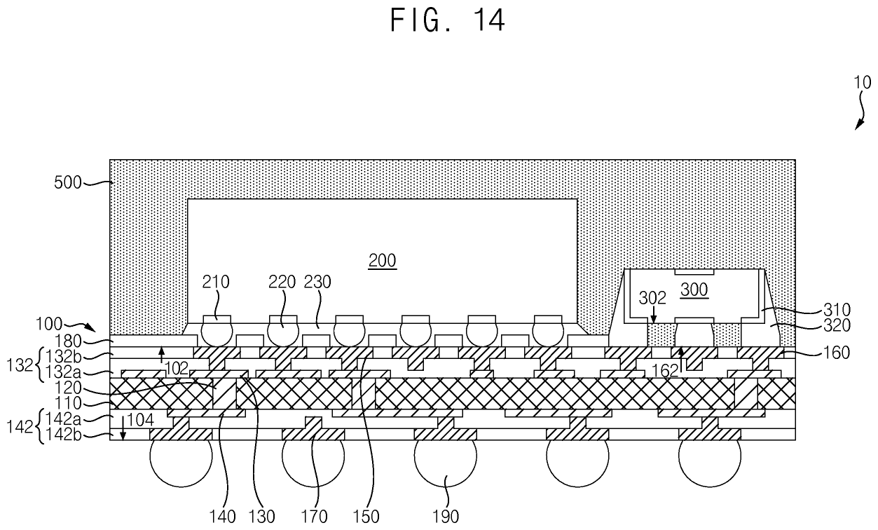

Referring to FIG. 14, external connection bumps 190 such as solder balls may be formed on the third substrate pads 170 of the second surface 104 of the package substrate 100, and a sealing member 500 may be formed on the package substrate 100 to cover the semiconductor device 200 and the semiconductor element 300, to complete a semiconductor package 10 of FIG. 1.

The external connection bump 190 may be formed on the third substrate pad 170. In particular, after a photoresist pattern having temporary openings is formed on the second surface 104 of the package substrate 100, the temporary openings of the photoresist pattern may be filled with a conductive material, the photoresist pattern may be removed and a reflow process may be performed to form the external connection bumps 190. For example, the conductive material may be formed by a plating process. In one or more examples, the external connection bump 190 may be formed by a screen printing method, a vapor deposition method, etc. For example, the external connection bump 190 may include a C4 bump.

The sealing member 500 may be formed on the package substrate 100 to cover the semiconductor device 200 and the semiconductor element 300. The sealing member 500 may fill a space between the package substrate 100 and the semiconductor element 300. Since a sufficient spacing distance is secured between the semiconductor element 300 and the package substrate 100 by the insulating structures 400, the sealing member 500 may sufficiently fill the space between the semiconductor element 300 and the package substrate 100, and voids may be advantageously prevented from occurring within the semiconductor package 10. In one or more examples, the sealing member may include an epoxy mold compound (EMC).

In one or more examples, a second adhesive may be underfilled between the semiconductor element 300 and the package substrate 100. The second adhesive may reinforce the gap between the semiconductor element 300 and the package substrate 100. Since a sufficient spacing distance is secured between the semiconductor element 300 and the package substrate 100 by the insulating structures 400, the second adhesive may sufficiently fill the gap between the semiconductor element 300 and the package substrate 100, and voids may be advantageously prevented from occurring within the semiconductor package 10.

As mentioned above, during the process of forming the uppermost insulating layer 180 on the package substrate 100, the plurality of insulating structures 400 may be formed together with the uppermost insulating layer 180. Since the plurality of insulating structures 400 may be formed without additional process equipment, manufacturing times and manufacturing costs may be reduced.

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present embodiments. Accordingly, all such modifications are intended to be included within the scope of example embodiments as defined in the claims.

What is claimed is:

1. A semiconductor package, comprising:
a package substrate having a first surface and a second surface opposite to each other, the package substrate comprising a plurality of first substrate pads and a plurality of second substrate pads that are exposed from the first surface, wherein the plurality of first substrate pads and the plurality of second substrate pads are electrically connected to each other;
a semiconductor device mounted on the first surface of the package substrate and electrically connected to the plurality of first substrate pads;
at least one semiconductor element on the package substrate, the at least one semiconductor element spaced apart from the semiconductor device, the at least one semiconductor element being mounted on the package substrate via solder members that are disposed on the plurality of second substrate pads; and
a plurality of insulating structures on the first surface of the package substrate to space a lower surface of the at least one semiconductor element from the first surface of the package substrate, each of the plurality of insulating structures having a lower insulator and an upper insulator stacked on the lower insulator.

2. The semiconductor package of claim 1, wherein the plurality of insulating structures further comprise an uppermost insulating layer that is provided on the first surface and expose at least portions of the plurality of second substrate pads, and
wherein the lower insulator and the uppermost insulating layer comprise a same insulating material.

3. The semiconductor package of claim 1, wherein the plurality of insulating structures are respectively provided on the second substrate pads and surrounded by the solder members.

4. The semiconductor package of claim 1, wherein the lower surface of the at least one semiconductor element is spaced apart from upper surfaces of the second substrate pads by a first distance, and the first distance is greater than or equal to 20 μm and less than or equal to 40 μm.

5. The semiconductor package of claim 1, wherein the at least one semiconductor element comprises a plurality of element pads that are exposed from the lower surface of the at least one semiconductor element and are electrically connected to the solder members.

6. The semiconductor package of claim 5, wherein each of the plurality of element pads has a first width,
wherein each of the plurality of insulating structures has a second width, and
wherein a ratio of the first width and the second width is within a range of 1/5 to 1/2.

7. The semiconductor package of claim 1, wherein the plurality of insulating structures are respectively provided on central regions of the second substrate pads.

8. The semiconductor package according to claim 1, wherein a height of each of the insulating structures is greater than or equal to 20 μm and less than or equal to 40 μm.

9. The semiconductor package of claim 1, wherein the at least one semiconductor element comprises at least one of a passive device, a multi-layer ceramic capacitor (MLCC), a low inductance chip capacitor (LICC), a die side capacitor (DSC), a land side capacitor (LSC), an inductor, and an integrated passive device (IPD).

10. The semiconductor package of claim 1, wherein the plurality of insulating structures comprise at least one of a die attach film (DAF), epoxy molding compound (EMC), epoxy resin, UV resin, polyurethane resin, polyurethane resin, silicone resin, and silica filler.

11. A method of manufacturing a semiconductor package, the method comprising:
providing a package substrate having a plurality of substrate pads that are exposed from a first surface of a package substrate;
forming a first insulating layer to cover the first surface of the package substrate;
removing at least portions of the first insulating layer to form a plurality of lower insulators on the first surface of the package substrate;
forming a second insulating layer on the first surface of the package substrate to cover the lower insulators;
removing at least portions of the second insulating layer to form a plurality of upper insulators on the plurality of lower insulators respectively; and
mounting a semiconductor element on the plurality of substrate pads via solder members.

12. The method of claim 11, wherein forming the plurality of lower insulators comprises forming the plurality of lower insulators on the plurality of substrate pads.

13. The method of claim 11, wherein upper surfaces of the substrate pads are spaced apart from a lower surface of the semiconductor element by a first distance, and the first distance is greater than or equal to 20 μm and less than or equal to 40 μm.

14. The method of claim 11, wherein the semiconductor element comprises a plurality of element pads that are exposed from a lower surface of the semiconductor element and are electrically connected to the solder members.

15. The method of claim 14, wherein each of the plurality of element pads has a first width,
wherein each of the upper and lower insulators has a second width, and
wherein a ratio of the first width and the second width is greater than or equal to 1/5 and less than or equal to 1/2.

16. The method of claim 11, wherein forming the plurality of lower insulators on the substrate pads comprises forming the lower insulators on central regions of the substrate pads.

17. The method of claim 11, wherein the lower insulators have a first height from the substrate pads, and
wherein the first height is greater than or equal to 10 μm and less than or equal to 20 μm.

18. The method of claim 11, wherein the upper insulators have a second height from the lower insulators, and
wherein the second height is greater than or equal to 10 μm and less than or equal to 20 μm.

19. The method of claim 11, wherein the semiconductor element comprises at least one of a passive device, a multi-layer ceramic capacitor (MLCC), a low inductance chip capacitor (LICC), a die side capacitor (DSC), a land side capacitor (LSC), an inductor, and an integrated passive device (IPD).

20. A semiconductor package, comprising:
a package substrate having a plurality of first substrate pads and a plurality of second substrate pads that are exposed from a first surface of the package substrate, wherein the plurality of first substrate pads and the plurality of second substrate pads are electrically connected to each other;
a semiconductor device mounted on the first surface of the package substrate and electrically connected to the plurality of first substrate pads;
a semiconductor element on the first surface of the package substrate, the semiconductor element spaced apart from the semiconductor device, the semiconductor element being mounted on the package substrate via solder members that are disposed on the plurality of second substrate pads; and
a plurality of insulating structures provided within the solder members on the plurality of second substrate pads respectively, each of the plurality of insulating structures comprising a lower insulator provided on a central region of the second substrate pads and an upper insulator provided on the lower insulator, wherein a lower surface of the semiconductor element is spaced from the first surface of the package substrate by the plurality of insulating structures.
